(19) United States
(12) Patent Application Publication
(10) Pub. No.: US 2025/0279152 A1
(43) Pub. Date: Sep. 4, 2025

(54) FLASH MEMORY TESTING MECHANISM CAPABLE OF OPTIMALLY MATCH ERROR BIT CORRECTION CAPABILITY OF DECODER WITH REAL NOISE

(71) Applicant: Silicon Motion, Inc., Hsinchu County (TW)

(72) Inventor: Shiuan-Hao Kuo, New Taipei City (TW)

(21) Appl. No.: 18/925,046

(22) Filed: Oct. 24, 2024

(30) Foreign Application Priority Data
Mar. 4, 2024 (TW) 113107688

(51) Int. Cl. G11C 29/56

(52) U.S. Cl. CPC G11C 29/56008; G11C 29/56016; G11C 2029/5602

(57) ABSTRACT

A decoding method includes: comparing a decoded result with a pre-decoded result of a codeword after decoding the codeword stored by a flash memory, to obtain statistic description parameter(s) in a 3D space for the codeword; determining whether a soft sensing step size currently used is matched to a log likely ratio of a decoder; when it is not matched, changing and adjusting the soft sensing step size to calculate change information of the statistic description parameter(s) caused by a change of the adjusted soft sensing step size to predict a match combination of a soft sensing step size and a corresponding log likely ratio; and using the match combination of predicted soft sensing step size and predicted corresponding log likely ratio to read a next codeword stored by the flash memory.

### BACKGROUND OF THE INVENTION

### 1. Field of the Invention

The invention relates to a flash memory testing mechanism, and more particularly to a decoding method used in a decoder of a flash memory controller, a flash memory controller, a host device for testing a flash memory, and a testing method of a flash memory.

### 2. Description of the Prior Art

Today's flash memory (e.g. NAND-type flash memory) technology has entered the generation of four-level cell unit (QLC, Quad-level cell) and five-level cell unit (PLC, Penta-level cell), and the number of bits will be up to four or five bits, i.e. the number of potentials will be up to 16-32 different potentials. It is quite easy to cause potential drift and overlap. Thus, the demand for soft decoding increases, and the correction capability of soft decoding is required to be higher. A traditional approach is to use the Additive white Gaussian Noise model (AWGN model) to simulate the noise of NAND-type flash memories and design related decoders. However, due to the complexity of the process technology and operating environment, the Gaussian noise model has also been unable to meet today's requirements.

### SUMMARY OF THE INVENTION

Therefore one of the objectives of the present invention is to provide a decoding method used in a decoder of a flash memory controller, a flash memory controller, a host device for testing a flash memory, and a testing method of a flash memory, to solve the problems of the traditional technology.

According to the embodiments, a decoding method used in a decoder of a flash memory controller is disclosed. The decoding method comprises: after decoding a codeword stored in a flash memory, comparing a decoded result of the codeword with a pre-decoded data of the codeword to obtain at least one statistical description parameter for describing the codeword in a three-dimensional space; determining whether a soft sensing step size, which is currently used, matches a log likelihood ratio of the decoder; when the soft sensing step size, which is currently used, does not match the log likelihood ratio of the decoder, changing and adjusting the soft sensing step size, and calculating a change of the soft sensing step size, which has been adjusted, for a change information caused by the at least one statistical description parameter to predict a match combination of a corresponding soft sensing step size and a corresponding log likelihood ratio; and, using the match combination of the predicted corresponding soft sensing step size and the predicted corresponding log likelihood ratio to read a next codeword stored in the flash memory.

According to the embodiments, a flash memory testing method is disclosed. The flash memory testing method comprises: before a mass production of a batch of flash memories, performing a pre-burn-in test upon the batch of flash memories; performing a read and write test upon the batch of flash memories under multiple different usage conditions to statistically obtain multiple different combinations of at least one statistical description parameter; using multiple different soft sensing step sizes to perform a read test upon the batch of flash memories under the multiple different usage conditions, to statistically obtain multiple variation combinations of the at least one statistical description parameter respectively corresponding to the multiple different soft sensing step sizes; statistically obtaining multiple parameter combinations of the at least one statistical description parameter respectively corresponding to the multiple different soft sensing step sizes used under the multiple different usage conditions according to the multiple variation combinations of the at least one statistical description parameter; depicting a graph of multiple different parameter combinations of the at least one statistical description parameter respectively corresponding to the multiple different soft sensing step sizes of the batch of flash memories to project the graph into a specific noise model to form a mesh structure; and, comparing and matching the mesh structure in the specific noise model with at least one contour line of an error bit correction capability of a decoder in a flash memory controller to obtain multiple corresponding optimal match combination information under the multiple different usage conditions to write and store a setting of the multiple corresponding optimal match combination information in a storage circuit or a firmware unit in the flash memory controller.

According to the embodiments, a flash memory controller, to be coupled between a host device and a flash memory, is disclosed. The flash memory controller comprises an encoder, a decoder, and a control unit. The encoder is used for performing an encoding operation upon a write data which is to be written into the flash memory by the host device. The decoder is used for performing a decoding operation upon a data stored by the flash memory. The control unit, coupled to the encoder and the decoder, is used for control the encoding operation and the decoding operation. After the decoder decodes a codeword stored in the flash memory, the control unit is used for: comparing a decoded result of the codeword with a pre-decoded data of the codeword to obtain at least one statistical description parameter for describing the codeword a in three-dimensional space; determining whether a soft sensing step size, which is currently used, matches a log likelihood ratio of the decoder; when the soft sensing step size, which is currently used, does not match the log likelihood ratio of the decoder, changing and adjusting the soft sensing step size, and calculating a change of the soft sensing step size, which has been adjusted, for a change information caused by the at least one statistical description parameter to predict a match combination of a corresponding soft sensing step size and a corresponding log likelihood ratio; and, using the match combination of the predicted corresponding soft sensing step size and the predicted corresponding log likelihood ratio to read and decode a next codeword stored in the flash memory.

According to the embodiments, a host device used for testing a flash memory is disclosed. The host device comprises a storage circuit and a processor circuit. The processor circuit, coupled to the storage circuit, is used for: before a mass production of a batch of flash memories, performing a pre-burn-in test upon the batch of flash memories; performing a read and write test upon the batch of flash memories under multiple different usage conditions to statistically obtain multiple different combinations of at least one statistical description parameter; using multiple different soft sensing step sizes to perform a read test upon the batch of flash memories under the multiple different usage conditions, to statistically obtain multiple variation combinations of the at least one statistical description parameter respectively corresponding to the multiple different soft sensing step sizes; statistically obtaining multiple parameter combinations of the at least one statistical description parameter respectively corresponding to the multiple different soft sensing step sizes used under the multiple different usage conditions according to the multiple variation combinations of the at least one statistical description parameter; depicting a graph of multiple different parameter combinations of the at least one statistical description parameter respectively corresponding to the multiple different soft sensing step sizes of the batch of flash memories to project the graph into a specific noise model to form a mesh structure; and, comparing and matching the mesh structure in the specific noise model with at least one contour line of an error bit correction capability of a decoder in a flash memory controller to obtain multiple corresponding optimal match combination information under the multiple different usage conditions to write and store a setting of the multiple corresponding optimal match combination information in a storage circuit or a firmware unit in the flash memory controller.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a flash memory controller according to an embodiment of the present invention.

FIG. 2 is a diagram of a flowchart for improving the decoding capability of the decoder of the flash memory controller according to an embodiment of the present invention.

FIG. 3 is a diagram of a flowchart for improving the decoding capability of a decoder of a flash memory controller according to an embodiment of the present invention.

FIG. 4 is a schematic diagram of ideal analysis and calculation for Gaussian noise according to an embodiment of the present invention.

FIG. 5 is a schematic diagram of multiple different statistical curved lines of different error bit numbers vs. different error rates FER according to an embodiment of the present invention.

FIG. 6 is a diagram showing an example of different error bit numbers corresponding to different values of SCR and SER under a condition of the host device (or flash memory controller) fixing the error rate FER as 1e−6 (i.e. 1×10⁻⁶) and another example of different error bit numbers corresponding to different values of SCR and SER under another condition of the host device (or flash memory controller) fixing the error rate FER as 1e−8 (i.e. 1×10⁻⁸) according to an embodiment of the present invention.

FIG. 7 is a schematic diagram of a surface of equivalent correction capability of a decoder in a three-dimensional (3D) space according to an embodiment of the present invention.

FIG. 8 is a schematic diagram showing a combination of the decoder's equivalent correction capability model and the ideal AWGN noise model according to an embodiment of the present invention.

FIG. 9 is a schematic diagram showing the deviations in different directions caused by different usage conditions in the ideal AWGN noise model shown in FIG. 8.

FIG. 10 is a schematic diagram of an example of statistical analysis by the host device (or flash memory controller) for the LLR values and the decoding capability of the decoder according to an embodiment of the present invention.

FIG. 11 is a schematic diagram of an example of projecting different proportions of the optimal LLR value combinations (LLR1, LLR2) at different coordinate points onto the three-dimensional space of the N4 noise model according to an embodiment of the present invention.

FIG. 12 is a schematic diagram of an example of a host device (or flash memory controller) fixing the LLR2 value at the value 13 and then changing different LLR1 values according to an embodiment of the present invention.

FIG. 13 is a diagram of the results of contour lines of correction capability using the preset LLR value.

FIG. 14 is a schematic diagram of the results of the contour lines of correction capability using the optimal LLR value.

FIG. 15 is a schematic diagram of the mesh structure of the SCR/SER combination under different Δ values under the ideal AWGN model according to an embodiment of the present invention.

### DETAILED DESCRIPTION

The present invention aims at providing and constructing a decoding operation/method and its decoding capability based on a non-Gaussian noise model, to find an optimal log-likelihood ratio (which can referred to as LLR value) and an optimal soft sensing step size (which can referred to as Δ value) to optimally match the error bit correction capability of a decoder with the real noise under the current usage condition, so as to enhance the correction capability up to the maximum potential.

According to the embodiment of the present invention, the present invention proposes a non-Gaussian N4 soft noise model (which can be referred to as N4 noise model for short), and further proposes the analysis method and design decoding sensing method that are most suitable for the decoder. The N4 noise model is based on N4 model which has the lowest soft message decoding cost and defines at least one statistical description parameter such as three parameters to form a three-dimensional space. Any point (e.g. coordinate point) in this three-dimensional space represents a corresponding possibility of N4 noise. The present invention is to analyze the decoding capability of the decoder through the N4 noise model to find out the research direction for optimizing the decoding capability and finally based on the LLR values and Δ values to obtain and complete a solution of a soft sensing method based on the minimum amount of soft messages that optimizes the LLR values and Δ values and is most suitable for the decoder. This can allow the decoder's correction capability to be maximized. Compared with the previous way of developing and analyzing decoders using AWGN models, the N4 noise model of the present invention covers all possibilities of real NAND-type flash memory noises, can simulate and find the optimal LLR value and Δ value, and can be used as a setting of soft message sensing operation without needing to rely on experience. This can be implemented in products.

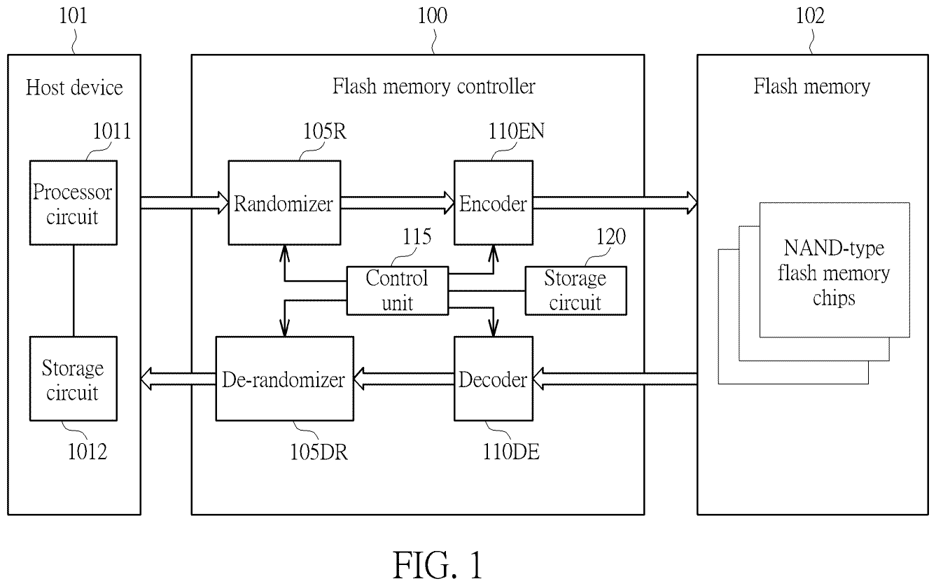

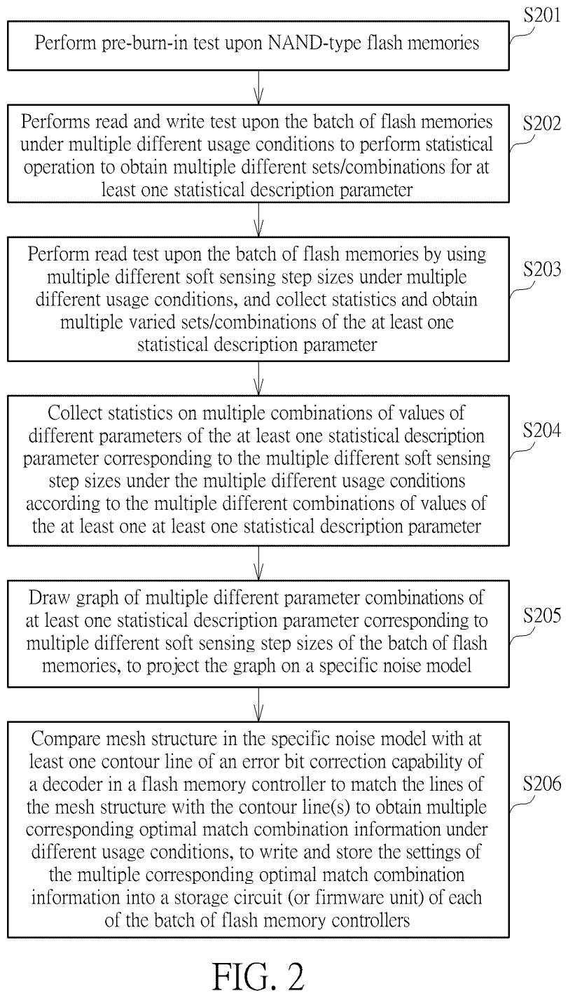

In order to make readers easily understand the device, operation and process of the embodiment of the present invention, please refer to FIG. 1 in conjunction with FIG. 2. FIG. 1 is a schematic diagram of the flash memory controller 100 according to the embodiment of the present invention. FIG. 2 is a schematic diagram of a flowchart for improving the decoding capability of the decoder of the flash memory controller 100 according to an embodiment of the present invention.

As shown in FIG. 1, the flash memory controller 100 is used to be coupled between a host device 101 and a flash memory module 102. The host device 101 includes a processor circuit 1011 and a storage circuit 1012. The flash memory controller 100 includes a randomizer 105R, a de-randomizer 105DR, an encoder 110EN, a decoder 110DE, a control unit (such as a control processing circuit) 115, and a storage circuit 120. The control unit 115 is used to set and control the randomizer 105R, the de-randomizer 105DR, the encoder 110EN, and the decoder 110DE, and the storage circuit 120 is for example a hardware or firmware and can be used to store corresponding control information, instructions, or parameters. The flash memory 102 is for example a flash memory module and includes one or more flash memory chips such as NAND-type flash memory chips.

In one embodiment, the host device 101 may be a computer device operated by the user after the flash memory 102 (or the flash memory controller 100) leaves the factory, and for example it is a data server (but not limited to). For example, when the host device 101 (or the processor circuit 1011) writes a data to one or more flash memory chips in the flash memory 102, the data to be written (for example simply called a write data) will first be sent to the flash memory controller 100. The randomizer 105R performs a randomization process operation upon the write data to generate a randomized write data to eliminate the data skew of the write data to reduce the occurrence of bit errors. Then the encoder 110EN performs an encoding processing operation such as low-density parity-check (LDPC) encoding process (but not limited) upon the randomized write data to generate an encoded write data, so as to write the encoded write data into one or more flash memory chips of the flash memory 102.

In addition, the host device 101 (or the processor circuit 1011) may request to read the data, which is previously written, from one or more flash memory chips in the flash memory 102, and the data requested to be read (referred to as read data) will first be sent to the flash memory controller 100. The decoder 110DE performs a decoding operation (such as LDPC decoding, but not limited) upon the read data to generate a decoded read data to send the decoded read data to the de-randomizer 105DR, and then the de-randomizer 105DR performs a de-randomization process operation upon the decoded read data to generate a de-randomized read data and transmit the de-randomized read data to the host device 101.

In addition, in one embodiment, the host device 101 may be a computer device operated by a tester before the flash memory module 102 (or the flash memory controller 100) leaves the factory. For example, the tester may use a computer device to respectively couple to a batch of different flash memory modules 102 (or flash memory controllers 100) to test the batch of different flash memory modules 102 (or flash memory controllers 100) respectively. For example, the host device 101 (or the processor circuit 1011) may also perform a write/read test upon one or more flash memory chips in the batch of different flash memory modules 102. The host device 101 can write a test data into one or more flash memory chips in a specific flash memory 102, and the test data will first be sent to the flash memory controller 100. The randomizer 105R performs a randomization process operation upon the test data to generate a randomized test data and eliminate the data skew of the test data to reduce the occurrence of bit errors, and then the encoder 110EN performs an encoding process operation (such as LDPC encoding process, but not limited to) upon the randomized test data to generate an encoded test data to write the encoded test data into one or more flash memory chips of flash memory 102.

In addition, the host device 101 (or the processor circuit 1011) may request to read previously written test data from one or more flash memory chips in the flash memory 102. The test will first be sent to the flash memory controller 100, and the decoder 110DE performs a decoding process operation (such as LDPC decoding process, but not limited to) upon the test data to generate a decoded test data, so as to transmit the decoded test data to the de-randomizer 105DR. Then the de-randomizer 105DR performs a de-randomization process operation upon the decoded test data to generate a de-randomized test data to send the de-randomized test data into the host device 101.

It should be noted that the operations of randomizer 105R and de-randomizer 105DR are a pair of operations. In another embodiment, the flash memory controller 100 may exclude the randomizer 105R and the de-randomizer 105DR. This modification is also suitable for the present invention. Furthermore, the host device 101 (or the processor circuit 1011) can perform test read/write upon one or more batches of flash memories to compare the original test data with the read de-randomized test data, so as to perform the statistical analysis to obtain statistical results of parameters (such as error bits) of multiple codewords of multiple test data.

The steps of the flowchart in FIG. 2 are detailed below:

Step S201: Before the mass production of a batch of NAND-type flash memories, the host device 101 (or processor circuit 1011) performs a pre-burn-in test upon the batch of NAND-type flash memories;

Step S202: The host device 101 (or the processor circuit 1011) performs a read and write test upon the batch of flash memories under multiple different usage conditions to perform a statistical operation to obtain multiple different sets/combinations for at least one statistical description parameter such as obtaining the different sets/combinations of three parameters, e.g. strong correct rate (SCR), strong error rate (SER), and the error bit number under different conditions such as different wear conditions, different writing times, and different read and write temperatures;

Step S203: The host device 101 (or the processor circuit 1011) performs the read test upon the batch of flash memories by using multiple different soft sensing step sizes under multiple different usage conditions, and collects statistics and obtains multiple varied sets/combinations of the at least one statistical description parameter corresponding to the multiple different soft sensing step sizes, such as collecting statistics and obtaining multiple variation combinations of the values of parameters such as the strong correct rate SCR, strong error rate SER, and so on when using different soft sensing step sizes (Δ values) to perform the read operation upon the flash memory under different wear conditions, different writing times, and different read and write temperatures;

Step S204: The host device 101 (or the processor circuit 1011) collects statistics on multiple combinations of values of different parameters of the at least one statistical description parameter corresponding to the multiple different soft sensing step sizes under the multiple different usage conditions according to the multiple different combinations of values of the at least one at least one statistical description parameter, e.g. collects statistics of the values of the SCR, SER, or/and error bit number when using different Δ values under various different wear conditions, writing times, and read and write temperatures;

Step S205: The host device 101 (or the processor circuit 1011) based on the multiple different combinations of values of the at least one at least one statistical description parameter, e.g. the values of the SCR, SER, and error bit number, draws a graph of multiple different parameter combinations (e.g. different combinations of different parameter values of parameters SCR/SER) of at least one statistical description parameter corresponding to the multiple different soft sensing step sizes of the batch of flash memories, to project the graph on a specific noise model (e.g. N4 noise model, but not limited) to form a mesh structure; and

Step S206: The host device 101 (or the processor circuit 1011) compares the mesh structure in the specific noise model with at least one contour line of an error bit correction capability of a decoder in a flash memory controller to match the lines of the mesh structure with the contour line(s) to obtain multiple corresponding optimal match combination information under different usage conditions, to write and store the settings of the multiple corresponding optimal match combination information into a storage circuit (or firmware unit) of each of the batch of flash memory controllers; for example, the lines of the mesh structure of the noise model of the NAND-type flash memories is compared and matched with the contour line(s) of the error bit correction capability of the decoder to obtain multiple corresponding optimal match combinations (LLR values and Δ values) under different wear conditions, writing times, and read and write temperatures conditions, and the settings of these corresponding optimal match combinations are written into the storage circuit 120 (or firmware unit) in the flash memory controller; furthermore, the batch of flash memories is, for example, multiple flash memories with the same process type parameters, and information of the above-mentioned corresponding optimal match combination refers to the information of multiple optimal log-likelihood ratios and multiple optimal soft sensing step sizes respectively under the multiple different usage conditions.

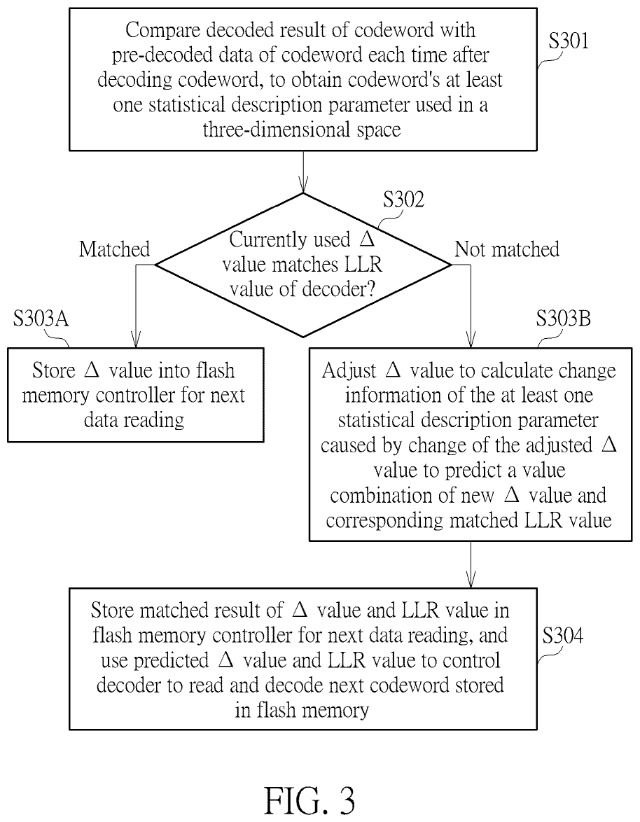

In addition, in one embodiment, the above-mentioned operations of statistical simulation, analysis, and judgment operations can also be implemented in a flash memory controller 100, so that the flash memory controller 100 can instantly respond to the different usage conditions of a flash memory 102 to optimize the Δ value and the LLR value used by a read operation. Refer to FIG. 1 in conjunction with FIG. 3. FIG. 3 is a schematic diagram of a flowchart for improving the decoding capability of the decoder 110DE of the flash memory controller 100 according to an embodiment of the present invention. The steps of the flowchart in FIG. 3 are detailed below:

Step S301: The flash memory controller 100 (or the control unit 115) compares a decoded result of the codeword with a pre-decoded data of the codeword each time after the decoder 110DE of the flash memory controller 100 completes decoding the codeword, to obtain the codeword's at least one statistical description parameter used in a three-dimensional space, e.g. comparing the decoded result with the pre-decoded data to obtain parameters such as a strong correct rate, a strong error rate, and an error bit number;

Step S302: The flash memory controller 100 (or the control unit 115) determines whether a currently used soft sensing step size matches the log likelihood ratio of the decoder or not, e.g. calculating and determining whether the currently used Δ value is matched to the LLR value of the decoder; if the two values are matched, the process proceeds to step S303A, otherwise, the process proceeds to step S303B;

Step S303A: When it is determined that the currently used Δ value is matched to the LLR value of the decoder, the flash memory controller 100 (or the control unit 115) stores the currently used Δ value into a storage circuit 120 or in decoder 110DE in the flash memory controller 110 for the next data reading;

Step S303B: When it is determined that the currently used Δ value is not matched to the LLR value of the decoder, the flash memory controller 100 (or the control unit 115) changes and adjusts the soft sensing step size, and calculates a change information of the at least one statistical description parameter caused by a change of the adjusted soft sensing step size to predict a match combination of a soft sensing step size and a corresponding log likelihood ratio, e.g. changing the different Δ values to calculate the change in SCR/SER caused by the increase/decrease of the Δ value to predict a value combination of a new Δ value and the corresponding matched LLR value; and

Step S304: The flash memory controller 100 (or the control unit 115) stores the matched result of the Δ value and the LLR value in the storage circuit 120 (or a firmware unit, or the decoder 110DE) of the flash memory controller 100 for the next data reading, and uses the match combination of the predicted soft sensing step size and the predicted corresponding log likelihood ratio to control the decoder to read and decode the next codeword which is stored in the flash memory.

It should be noted that, in the above embodiments, the control unit 115 is used to use a parameter combination of the strong correct rate, the strong error rate, and the error bit number to depict the codeword's coordinate point in the three-dimensional space in a specific noise model. In addition, the control unit 115 can calculate the change information of the at least one statistical description parameter caused by the change of the adjusted soft sensing step size to obtain at least one parameter combination corresponding to the match combination of the predicted soft sensing step size and the corresponding log likelihood ratio, to make the at least one parameter combination's coordinate point in the three-dimensional space fall within a specific match area. The specific match area is the area in which a smallest angle is formed by a line of a mesh structure of a specific noise model and a line of a decoding correction capability corresponding to the corresponding log likelihood ratio.

The simulation operation, analysis operation, judgment operation, flow process, and methods in the embodiments of the present invention are applicable to all flash memories on the market, e.g. three-dimensional NAND-type flash memories (but not limited to). In addition, they can also be customized according to customer requirements and implemented to be applied into any kinds of flash memory controller products.

In addition, the statistical simulation, analysis and judgment operation methods of the embodiments of the present invention can be implemented in a flash memory controller and/or in a host device (e.g. a computer device) which is used to perform the initialization process upon multiple storage devices which include multiple flash memory controllers respectively. The following paragraphs detail the embodiments of the present invention, so that the concepts and related content of the embodiments of the present invention can be more clearly understood for the readers.

Generally, the design of decoders in conventional flash memory controllers is mostly based on the AWGN model. However, with the complexity of the process technology, operating conditions, and operation environment of NAND-type flash memory, the difference between the real noise of the flash memory and the ideal noise simulated by the AWGN model will be gradually expanded. Therefore, it is extremely necessary to find out a noise model that can be more close to the real noise to improve the correction capability of the decoder of flash memory controller.

To this end, the embodiment of the present invention performs the simulation operation of soft sensing under the AWGN model and the probability estimations of the potential intervals, selects a specific noise model (such as the N4 model, but not limited to) with lower or lowest soft message decoding cost as a design basis, finds out multiple parameters (such as three parameters) that can describe all possible noise points (such as N4 noise) in the specific noise model, and uses these three parameters to form a three-dimensional space, wherein each of all the N4 noise points can be represented by a point in this three-dimensional space. The method of the decoder 110DE of the present invention is performed based on a basis of the model of this three-dimensional space. By using the operation of the decoder 110DE and analyzing the operation of soft sensing, and each result can be depicted in the three-dimensional space so as to find out the optimal result of the two operations to determine at least one parameter value used in a resultant mode of a sensing operation.

The decoder 110DE adopts the LDPC decoding operation. The flash memory controller 100 (or the host device 101) applies the LDPC encoding/decoding operation into the N4 noise model for simulation to construct a parameter table of the three-dimensional space, uses the contouring drawing method to draw the overlapping surfaces in the three-dimensional space to present the equivalent correction capability. Based on the figure, when adjusting different LLR values of the decoder 110DE under the N4 noise model, the different changes of the contour lines of the correction capability is obtained. By the statistical induction, an optimal LLR value of the decoder 110DE can be configured in response to a noise's specific point (not limited) in the three-dimensional space.

In the operation of soft sensing, the embodiment of the present invention takes the AWGN model (but not limited to) as an example. The flash memory controller 100 (or the host device 101 controls the flash memory controller 100) changes the different value of soft sensing step size (Δ value) to generate a different change result in the three-dimensional space. By further changing the Δ value of the AWGN model, this can draw the change generated in the three-dimensional space projected by the mesh structure of different values of Δ value and SCR/SER.

Through the above operations, the present invention can obtain different results of the correction capability of the decoder 110DE in response to the change generated in the different Δ values, and also achieve adjusting both the LLR value and the Δ value to make the decoder 110DE be more closely matched with the N4 noise model. Therefore, the embodiments of the present invention can simulate and analyze different coordinate points of various kinds of SCR/SER combinations in the N4 noise model to find out the optimal LLR value, and can determine how to find out the optimal setting of the LLR value and Δ value which are best matched in an example of the AWGN model. In this way, the decoder 110DE of the present invention can be applied to NAND-type flash memories operating under any different kinds of usage conditions.

In short, the flash memory controller 100 (or the host device 101 controls the flash memory controller 100) in the present invention uses a NAND-type flash memory, which operates under various kinds of nose conditions, to change different Δ values to perform sensing of N4 model and depict the results at different coordinate points in a three-dimensional space, and then uses the contour lines of the correction capability of the decoder 110DE to find out and configure a setting of an optimal LLR value and a Δ value. Therefore, the present invention not only constructs an N4 soft message noise model for non-Gaussian noise, but also uses this model to implement a decoding method based on the minimum amount of soft message passing for non-Gaussian noise.

In practice, for example, before mass production of various kinds of products, the optimal match combinations of LLR values and Δ values for the different products under the condition of various simulated noises can be measured for the first, and then these setting values of the optimal match combinations can be preset in the storage circuit or firmware unit in the corresponding flash memory controller, so that the setting values can be used as a reference for subsequent actual operations of NAND-type flash memories and are applicable to all 3D NAND-type flash memories on the market.

The following describes the noise model in the embodiments of the present invention. The factors that affect the actual noise of NAND-type flash memories are very complex. According to different technologies, different manufacture companies, and the usage conditions of NAND-type flash memories, the variation characteristics of noise are different. In order to simplify the calculation analysis and judgment operations, the decoder and its operation/method of the present invention are designed to improve the decoding ability under various kinds of noise conditions of NAND-type flash memories as much as possible. In the embodiments, the N4 noise model with the relatively low soft message decoding cost is provided as an example for illustrative purposes. However, this is not intended to be a limitation of the present invention. In other embodiments, examples of different noise models can also be used to implement it.

At first, each parameter in an N4 noise model is analyzed so that a noise model constructed by adjusting all parameters can cover all actual noise conditions that an NAND-type flash memory may encounter. An N4 noise model divides the potential into four intervals according to the sign bit and the soft bit. Therefore, only three parameters are needed to describe the possibilities of all noises in the N4 noise model. The definitions of the three parameters are, for example, a strong error rate (SER), a strong correct rate (SCR), and an error bit number. The error bit number refers to the number of error bits in a segment of data bits such as one codeword' s length (but not limited to). The strong error rate refers to the proportion of strongly erroneous bits of all error bits in the segment of data bits. The strong correct rate refers to the proportion of strongly correct bits of all the correct bits in the segment of data bits.

Ideally, it can be assumed that the potentials in the storage cells of each NAND-type flash memory have a Gaussian distribution. If a raw bit error rate (RBER) is given, a variation σ (or called as standard deviation) of the Gaussian distribution can be inversely calculated. When a sensing operation of NAND-type flash memory obtains a soft bit (which is also known as reliability), the sensing point will be shifted to the left (i.e. Negative Sensing, NS) and also to the right (Positive Sensing, PS), and a potential inside an interval between the NS point and the PS point is regarded as a low reliability while another potential outside such interval is regarded as a high reliability. NS and PS need to exist in pairs, and the operation is called as soft sensing which is used to calculate whether the potential of a storage cell of the NAND-type flash memory is located between the NS point and the PS point.

In one embodiment, the present invention may perform the hard sensing (which uses a middle potential to distinguish and obtain a sign bit) for one time, the NS sensing for one time and the PS sensing for one time, i.e. the total number of the sensing operations is equal to three, and the range of possible potentials is divided into four intervals according to the sign bit and the soft bit, which can be called as a three-time trial sensing operation or N4 operation. In addition, in one embodiment, the soft sensing operation can also be performed for multiple times. For example, the present invention may perform the hard sensing for one time, and the soft sensing for two times (NS sensing for two times and PS sensing for two times) and can be called as a five-time trial sensing operation or N6 operation. Similarly, performing the hard sensing for one time and three-time soft sensing (NS sensing for three times and PS sensing for three times) can be called as a seven-time trial sensing operation or N8 operation.

In addition, the distance between each left shift point (NS point) and right shift point (PS point) is called as the soft sensing step size, which is represented by a Δ value. For example, the Δ value can ideally be a half of the standard deviation σ, represented by Δ=σ/2. Ideally, the step size of each interval is a half of the standard deviation σ, and thus the probability that the a potential of a storage cell of the NAND-type flash memory falls within each interval can be calculated by using a corresponding erfc function. The four intervals of the potential can be marked as a strong correct interval, a weak correct interval, a weak error interval, and a strong error interval, respectively. Compared to hard sensing, the N4 operation is the soft sensing decoding operation having lowest-cost.

Following the above, the N4 sensing decoding operation is applied to a noise model to obtain the aforementioned N4 noise model, to use three parameters to describe all noise possibilities in the N4 noise model. For example, assuming that a codeword having a length of n bits has the number e of error bits and the remaining (n−e) correct bits under a condition of giving the values of the strong error rate SER and the strong correct rate SCR, the present invention based on the strong error rate SER and the strong correct rate SCR can calculate that the number of strongly erroneous bits is SER×e and the number of strongly correct bits is SCR×(n−e), and then can calculate the number of weak error bits as (1−SER)×e and calculate the number of weak correct bits as (1−SCR)×(n−e).

Then, for example, the present invention may distribute the positions of the strong error bits, weak error bits, strong correct bits, and weak correct bits in the codeword in a random number manner to make sure that the bits do not overlap, and thus the noise distribution of a codeword is completed. In this way, the N4 noise model of a codeword can be described by the above three parameters, and the three parameters of the strong error rate SER, the strong correct rate SCR, and the error bit number can be used to form a three-dimensional space. Any point in this three-dimensional space represents a possibility of N4 noise.

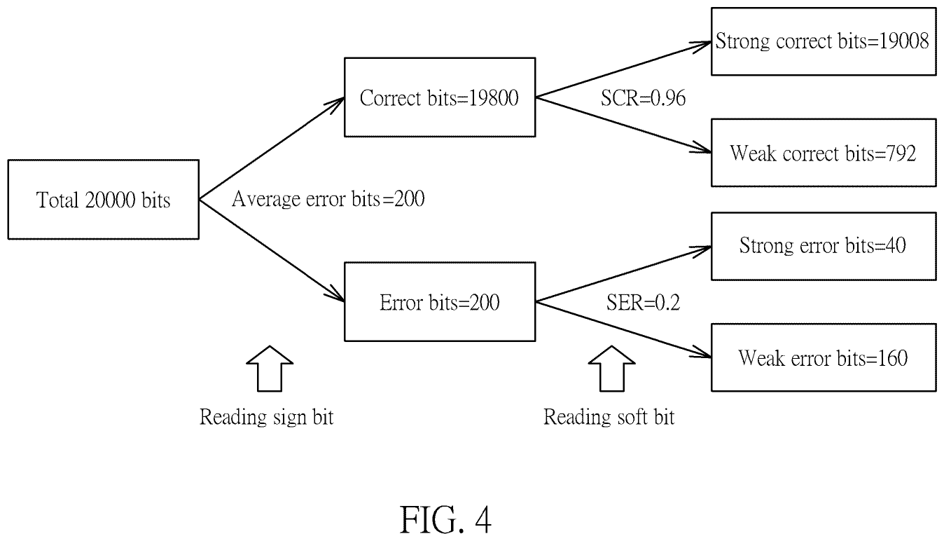

For example, FIG. 4 is a schematic diagram of ideal analysis and calculation of Gaussian noise (but not limited to) according to an embodiment of the present invention. As shown in FIG. 4, for an LDPC codec with a raw bit error rate RBER of Gaussian noise being equal to 0.01 and a length of 20000 bits, the average number of error bits is, for example, 200 bits, the strong error rate SER is 0.2, and the strong correct rate SCR is 0.96. Therefore, the number of strong correct bits is equal to 0.96×19800=19008, the number of weak correct bits is equal to 792, and the number of strong error bits is equal to 0.2×200=40, the number of weak error bits is equal to 160. Ideally, Gaussian noise is independent of each bit. The measurement result of a single codeword may not be exactly equal to the average value. Therefore, in the three-dimensional N4 noise model, the Gaussian noise having the raw bit error rate RBER being equal to 0.01 is represented by a sphere centered on a coordinate point corresponding to a combination of strong error rate SER=0.2, strong correctness rate SCR=0.96, and number of error bits=200.

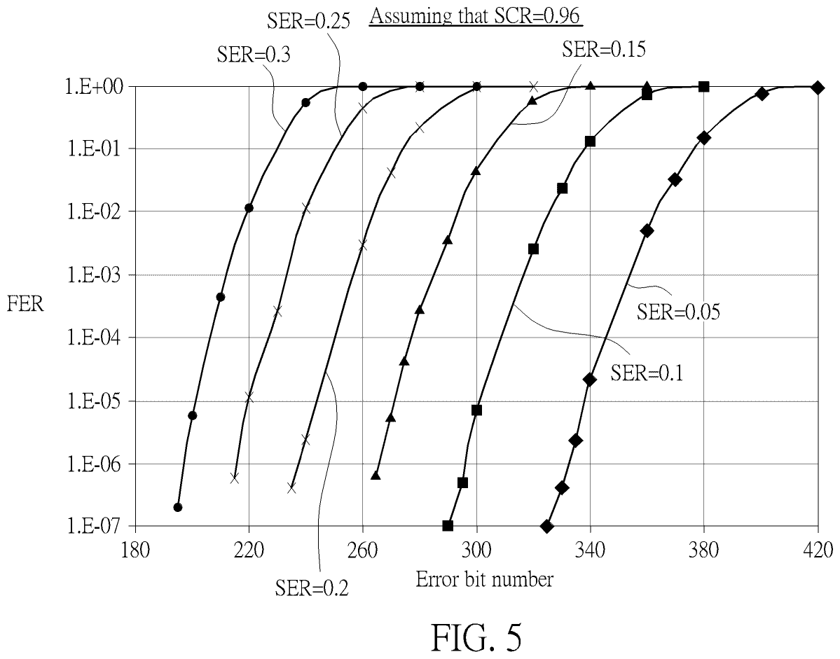

In the following, the embodiment of the present invention performs statistical analysis and calculations for the decoding capability of the LDPC decoder. First, under the conditions of fixing different values of strong error rate SER and different values of strong correctness rate SCR, the present invention performs the statistical analysis upon the conditions of different error bit numbers, to obtain a curve (curved line) which represents the result of the error bit number vs. the frame error rate (FER, or called as a codeword error rate). For example, FIG. 5 is a schematic diagram of multiple different statistical curves of results of different error bit numbers vs. different frame error rates FER according to an embodiment of the present invention. As shown in FIG. 5, for example, when the strong correct rate SCR is fixed at 0.96 and the strong error rate SER has different changes from 0.05, 0.10, 0.15, 0.2, 0.25 to 0.30, the error rate FER having the different values can be statistically obtained under the conditions of different error bit numbers, and this indicates that the decoding capability of the same LDPC decoder 110DE is not the same under different usage conditions for a flash memory.

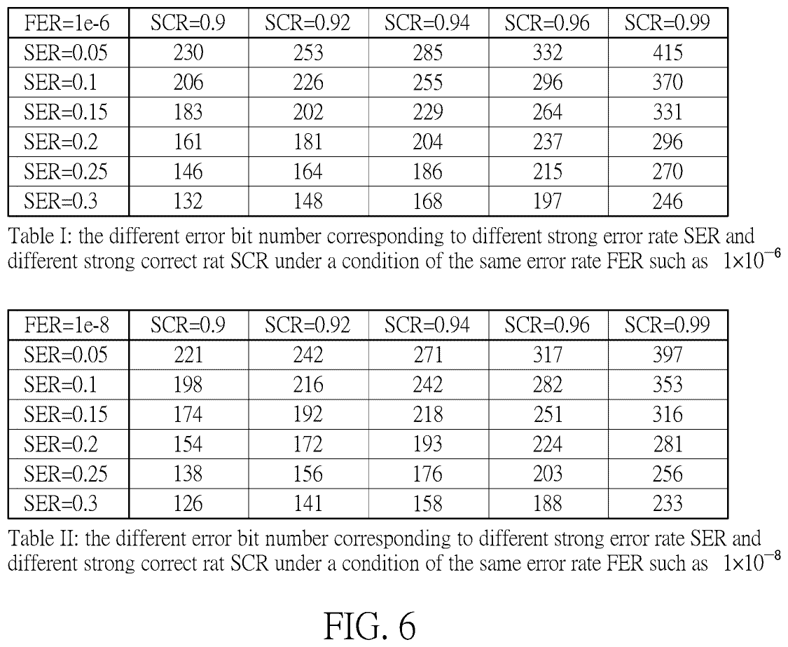

After statistically counting and collecting all the data, for example, the present invention can construct the information data of different error rates FER. For example, please refer to FIG. 6. FIG. 6 is a diagram showing an example of different error bit numbers corresponding to different values of SCR and SER under a condition of the host device (or flash memory controller) fixing the error rate FER as 1e−6 (i.e. 1×10⁻⁶) and another example of different error bit numbers corresponding to different values of SCR and SER under another condition of the host device 101 (or flash memory controller 100) fixing the error rate FER as 1e−8 (i.e. 1×10⁻⁸) according to an embodiment of the present invention. As shown in FIG. 6, the example of Table I indicates the different error bit number corresponding to different strong error rate SER and different strong correct rat SCR under a condition of the same error rate FER such as 1×10⁻⁶, and the example of Table II indicates the different error bit number corresponding to different strong error rate SER and different strong correct rat SCR under a condition of the same error rate FER such as 1×10⁻⁸. Any of fields in Table I and Table II equivalently can be used to describe a surface in the three-dimensional space. For example, the X-axis represents different values of the strong correct rate SCR, the Y-axis represents different values of the strong error rate SER, and Z-axis represents different error bit numbers. For example, the numerical values in each field of the two tables can be correspondingly drawn in a three-dimensional space to make any two adjacent points be connected to each other to form a surface. Each point on this surface is associated with the same error rate FER equivalently.

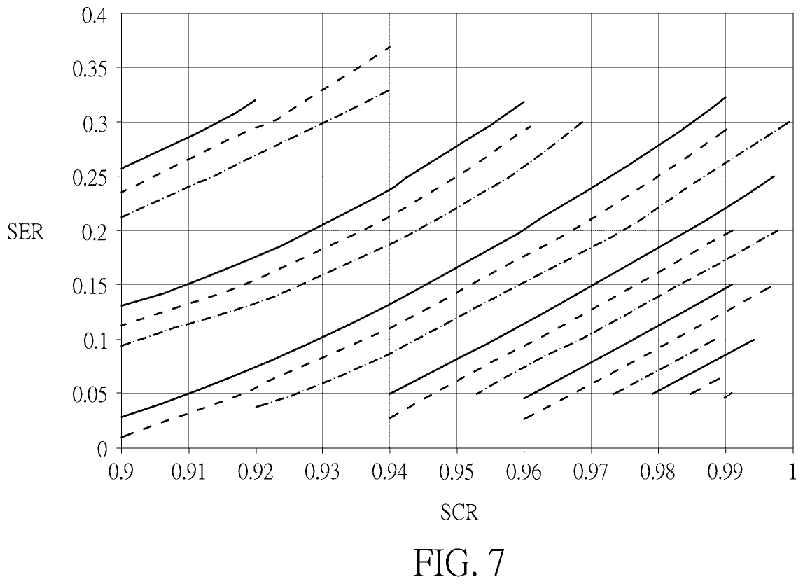

Since it is difficult to render overlapping surfaces in the three-dimensional drawing, the host device 101 (or the flash memory controller 100) in the embodiment of the present invention can be used to draw the surface in the 3D space in the form of contour lines. For example, please refer to FIG. 7. FIG. 7 is a schematic diagram of a surface of equivalent correction capability of a decoder in a 3D space according to an embodiment of the present invention. As shown in FIG. 7, the X-axis indicates the different values of the strong correct rate SCR, the Y-axis indicates the different values of the strong error rate SER, and the Z-axis of the three-dimensional space is the number of error bits, which is not shown in FIG. 7 Z axis, so FIG. 7 is regarded as the projection of this three-dimensional space on the X-Y plane. As shown in FIG. 7, the three different kinds of lines (solid lines, dashed line and dashed-dotted line) in FIG. 7 respectively represent three different kinds of surfaces, wherein the solid lines represent the same error rate FER of 1e−4 at different heights (i.e. different error bit numbers) of multiple surfaces, the dashed lines represent the same error rate FER of 1e−6 at different heights (i.e. different error bit numbers) of multiple surfaces, and the dashed-dotted lines represent the same error rate FER of 1e−8 at different heights (i.e. different error bit numbers) of multiple surfaces. The different heights (i.e. different error bit numbers) from the upper left to the lower right are 150, 200, 250, 300, 350, and 400 respectively. However, this is not a limitation of the present invention; in other embodiments, the values of equivalent correction capability at different surfaces may also be different.

As shown in FIG. 7, it briefly presents the difference of the equivalent correction capability of the decoder in the embodiment of the present invention. For example, if the error rate FER is required to be equal to 1e−4 and 200 bit errors can also be successfully decoded, then the requirements for the equivalent correction capability of the decoder 110DE may be for example a combination of the SCR being equal to 0.95 and the SER being equal to 0.28 or may be a combination of SCR being equal to 0.9 and the SER being equal to 0.15. In addition, in other examples, if it is desired to increase the correction capability from 200 bits up to 250 bits under the condition of fixing the strong correct rate SCR at 0.96, then it should be needed to decrease the strong error rate SER from 0.32 down to 0.2 or should be needed to adopt the example of the storing error number being equal to 50 and weak error number being equal to 200 without using the example of storing error number being equal to 64 and weak error number being equal to 136. The modifications are not limitations of the present invention.

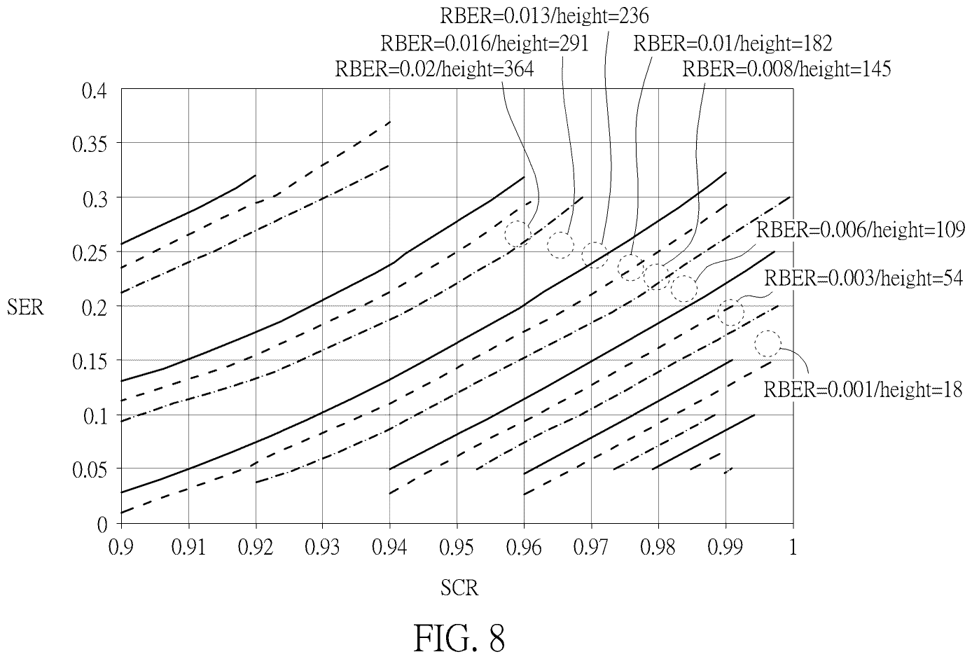

In addition, based on the model of decoder's equivalent correction capability shown in FIG. 7, the host device 101 (or the flash memory controller 100) of the embodiment of the present invention can also depict the ideal AWGN noise model into the surface diagram shown by the equivalent correction capability of the decoder 110DE. Please refer to FIG. 8. FIG. 8 is a schematic diagram showing a combination of the decoder's equivalent correction capability model and the ideal AWGN noise model according to an embodiment of the present invention. As shown in FIG. 8, each dashed circle in the figure represents a noise projection of the AWGN model. Taking the raw bit error rate (RBER) being equal to 0.01 as an example, a noise projection in a three-dimensional space is a sphere, and the center of the sphere is at (SER=0.2354, SCR=0.9759), and the height in the three-dimensional space is approximately 182 or 183 (but not limited). It can be seen that the multiple noise projections of the AWGN model equivalently form a tunnel shape in the three-dimensional space, and occupy only a small portion of the three-dimensional space. This tunnel ranges from a low RBER value to a high RBER value, and moves from the lower right to the upper left with its height gradually increasing. In addition, from the contour lines of the correction capability of the LDPC decoder 110DE, it can be seen that the surfaces of the LDPC decoding capability have the highest points in the lower right corner and begins to decrease toward the upper left corner. In this way, the host device 101 (or the flash memory controller 100) can determine the intersection portion/region of the tunnel shape of the noise projections of the AWGN noise model and decoding correction capability of the decoder 110DE in the three-dimensional space. The intersection portion/region indicates the decoding capability of the decoder using the AWGN noise model.

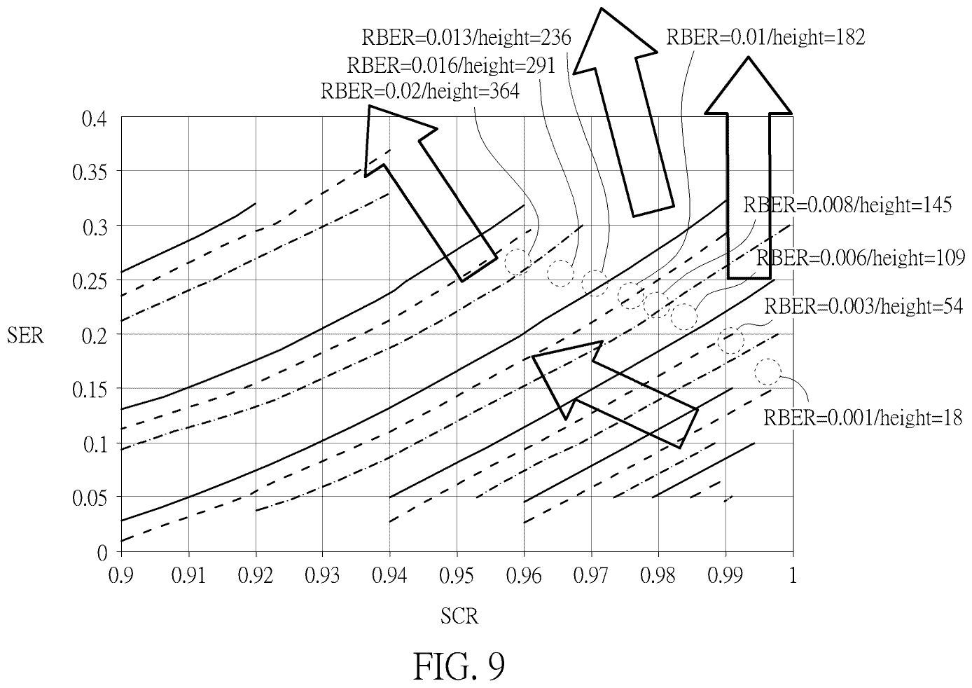

It should be noted that the ideal AWGN noise model represents the noise characteristics of a NAND-type flash memory when it is just shipped from the factory and is still in a healthy state. During the use of the NAND-type flash memory, various usage scenarios may cause the NAND-type flash memory to suffer different types of wear and tear, and this may cause the real noise of NAND-type flash memory to deviate from the ideal AWGN noise model. For example, please refer to FIG. 9. FIG. 9 is a schematic diagram showing the deviations in different directions caused by different usage conditions in the ideal AWGN noise model shown in FIG. 8. FIG. 9 is a schematic diagram of the deviation in different directions caused by different usage conditions in the ideal AWGN noise model shown in FIG. 8. Therefore, in the embodiments of the present invention, the decoder 110DE in the flash memory controller 100 is designed based on the ideal AWGN noise model at first and then further statistically analyzes the decoding capability of the decoder 110De in the three-dimensional space under the different usage conditions of the flash memory so as to improve the decoding correction capability.

In the following the decoder 110DE begins a statistical analysis of the decoding capability of the decoder 110DE in the three-dimensional space to determine how its decoding correction capability can be further improved under different usage conditions of the flash memory. In practice, in the embodiment of the present invention, the host device 101 (or the flash memory controller 100) calculates a value of an obtained input log likelihood ratio (LLR value) based on the parameters of the N4 noise model, to adjust the value of the obtained input LLR value to perform verification to improve the decoding correction capability of the LDPC decoder in the three-dimensional space of the N4 noise model. In another embodiment, in the three-dimensional space of the N4 noise model, the host device 101 (or the flash memory controller 100) can also calculate the input LLR value based on the strong error rate SER, the strong correct rate SCR, and the error bit number. However, if the LLR value is quantized, then the bit number of the quantized value will become smaller, and there will be a difference between the actual LLR value and the quantized value of LLR value. Therefore, in the embodiments of the present invention, the host device 101 (or the flash memory controller 100) performs a simulation statistical analysis and judgment operation upon all possible combinations of LLR values.

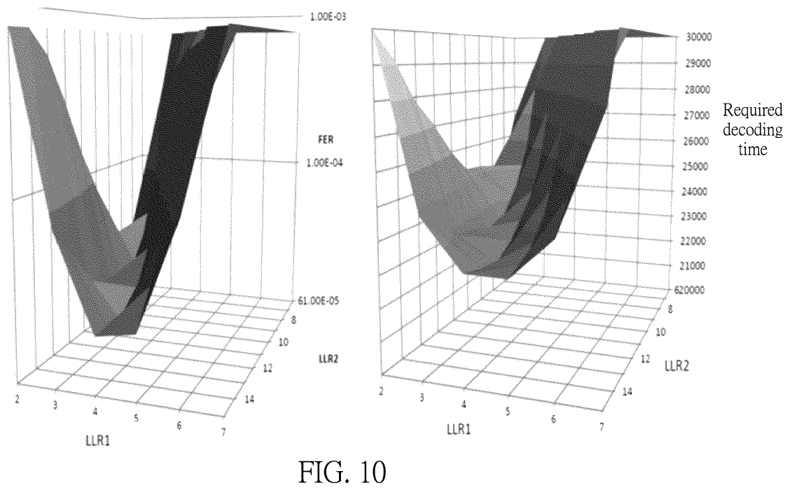

The number of soft bit in the N4 model is 1, and it is used to distinguish whether the bit is a strong bit or a weak bit. Under the assumption of symmetry, there may be two absolute values of LLR values, LLR2 and LLR1. Therefore, it is chosen to use the value of LLR2 for the strong bit, and to use the value of LLR1 for the weak bit, wherein the LLR2 value is greater than the LLR1 value. Please refer to FIG. 10. FIG. 10 is a schematic diagram of an example of statistical analysis by the host device 101 (or flash memory controller 100) for the LLR values and the decoding capability of the decoder according to an embodiment of the present invention.

The X-axis indicates LLR1 values of the weak bit, and the Y-axis indicates LLR2 values of the strong bit. As shown in the left half of FIG. 10, the Z-axis indicates the values of error rate FER. As shown in the right half of FIG. 10, the Z-axis indicates the required decoding time which can be used to represent the decoding capability of the decoder. As shown in FIG. 10, using different LLR values has different impacts on its decoding capability, and the LLR values with better decoding capabilities (or shorter time) will form a valley on the figure as well as the ratio of LLR1 to LLR2 at the valley is almost roughly identical. In this way, the host device 101 (or the flash memory controller 100) of the present invention can make the decoding capability of the LDPC decoder 110DE be more consistent with the N4 noise model by changing and optimizing the LLR values, thereby avoiding the offset of the LLR values and improving the error correction capability of the decoder 110DE. It should be noted that, in the three-dimensional space of the N4 noise model, the optimal LLR values corresponding to each coordinate points may be different.

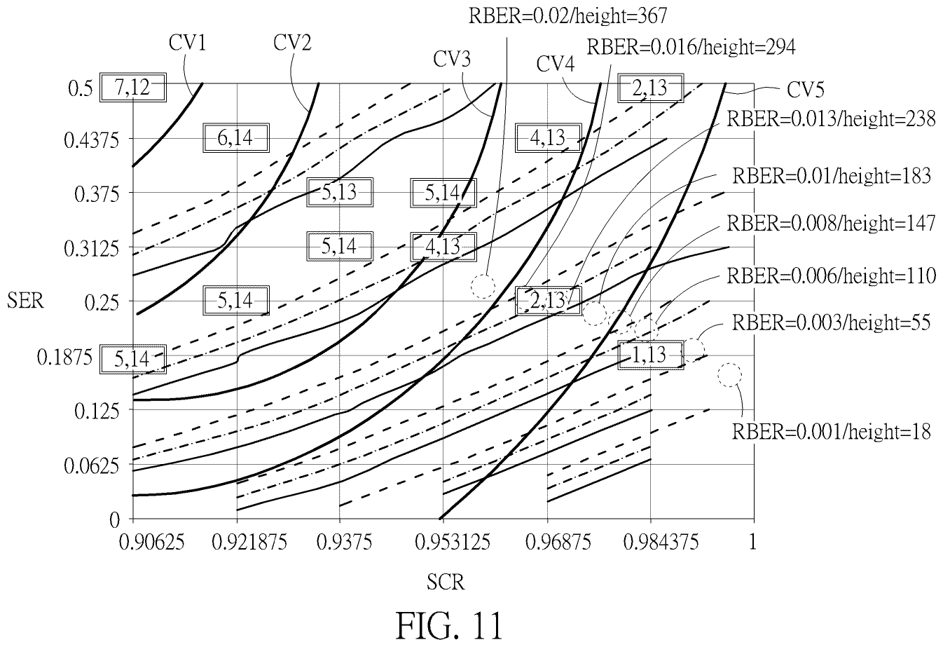

Therefore the host device 101 (or the flash memory controller 100) of the embodiment of the present invention performs statistics and analysis operations upon different coordinate points of different SCR/SER combinations in the three-dimensional space of the N4 noise model to find out the optimal LLR values of different coordinate points and mark them on different projections of different coordinate points of the SCR/SER combinations. Please refer to FIG. 11. FIG. 11 is a schematic diagram of an example of projecting different proportions of the optimal LLR value combinations (LLR1, LLR2) at different coordinate points onto the three-dimensional space of the N4 noise model according to an embodiment of the present invention. As shown in FIG. 11, when the embodiment of the present invention projects the proportional values (i.e. ratios) of different optimal LLR values (LLR1, LLR2) at different coordinate points into the three-dimensional space of the N4 noise model, the present invention based on the different proportional values of the combinations of optimal LLR values (LLR1, LLR2) divides multiple different SCR/SER planes into several regions/areas by using multiple bold curve lines CV1, CV2, CV3, CV4 and CV5, so as to make the proportional values LLR2/LLR1 of optimal LLR values (LLR1, LLR2) of different SCE/SER planes in each region/area is almost every close to each other and can be regarded as identical values substantially. For example, as shown in FIG. 11, the optimal LLR values (LLR1, LLR2) in the region at the left side of curve CV1 are equal to (7,12), and the optimal LLR values (LLR1, LLR2) in the region between curves CV1 and CV2 are equal to (6,14). The optimal LLR values (LLR1, LLR2) in the region between curves CV2 and CV3 are equal to (5,14) or (5,13). The optimal LLR values (LLR1, LLR2) in the region between curves CV3 and CV4 are equal to (4,13), and the optimal LLR values (LLR1, LLR2) in the region between curves CV4 and CV5 are equal to (2,13). The optimal LLR values (LLR1, LLR2) in the region at the right side of the curve CV5 are equal to (1,13). Furthermore, it should be noted that as shown in FIG. 8 several different LLR2 values may be between 12 and 14.

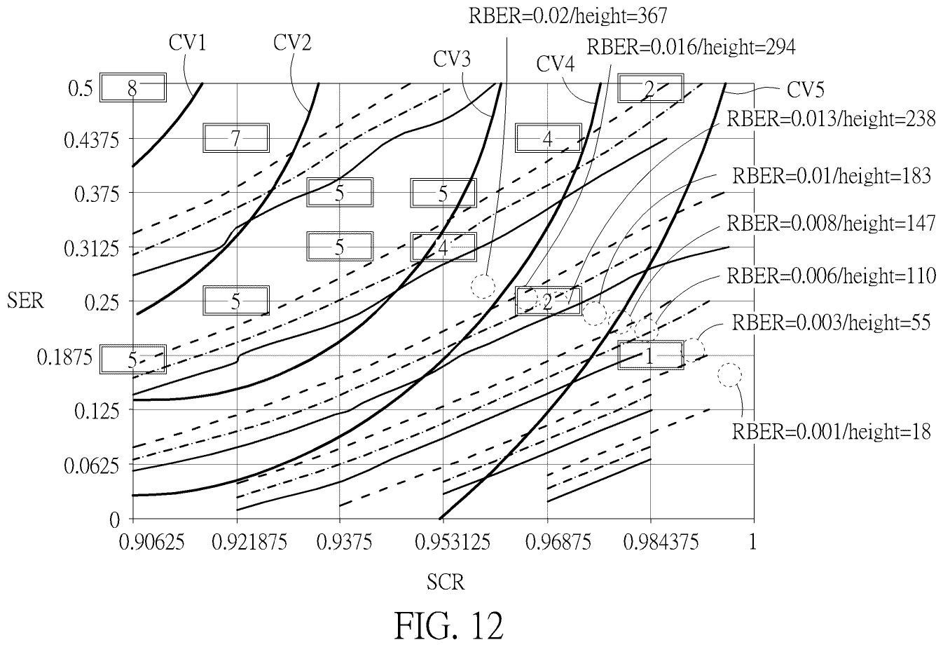

In one embodiment, the optimal LLR2 values may all fall between 12 and 14, and which are equivalently considered to be very close. Therefore, for example, the host device 101 (or flash memory controller 100) may fix the optimal LLR2 values as to the same value such as 13 (but not limited to) to simplify the complexity of statistics and analysis operations. That is to say, the embodiment of the present invention fixes the LLR2 value and only changes the value of LLR1 to reduce the complexity of system operation analysis. Please refer to FIG. 12. FIG. 12 is a schematic diagram of an example of a host device 101 (or flash memory controller 100) fixing the LLR2 value at the value 13 and then changing different LLR1 values according to an embodiment of the present invention. As shown in FIG. 12, the present invention is used to re-mark the corresponding optimal LLR1 values of different coordinate points on FIG. 12. It should be noted that these corresponding optimal LLR1 values are the same as the embodiment shown in FIG. 11.

In other words, the host device 101 (or the flash memory controller 100) of the present invention uses the simulation, statistics, and analysis operations to find out a changing trend of the optimal LLR values, so that the result of the simulation, statistics, and analysis operations can be applied to various kinds of NAND-type flash memory devices which operate under various kinds of usage scenarios/conditions. For example, even though during the use of NAND-type flash memories, it is impossible to know the parameters such as error bit number, SCR, and SER of each LDPC codeword before the codeword is successfully decoded, the embodiments of the present invention can use the statistical results of the previously successfully decoded LDPC codewords to predict the optimal LLR values for the setting of the next decoding.

In addition, in another embodiment, before mass production of each batch of NAND-type flash memories, the present invention may use the pre-burn-in test to obtain the parameters SCR, SER to predict an optimal LLR value to write and store the predicted optimal LLR value into the storage circuit (or firmware component) in a flash memory controller.

In addition, in an embodiment, the present invention may perform a statistics operation to determine the changing trend of the parameters SCR, SER to predict an optimal LLR value and to write and store the predicted optimal LLR value into the storage circuit (or firmware component) in a flash memory controller when it is in different conditions such as the number of program/erase (P/E) cycle increases, different read and write temperatures, or different potential slips, etc. All of these modifications are different implementation variations of the present invention and are not limitations of the present invention.

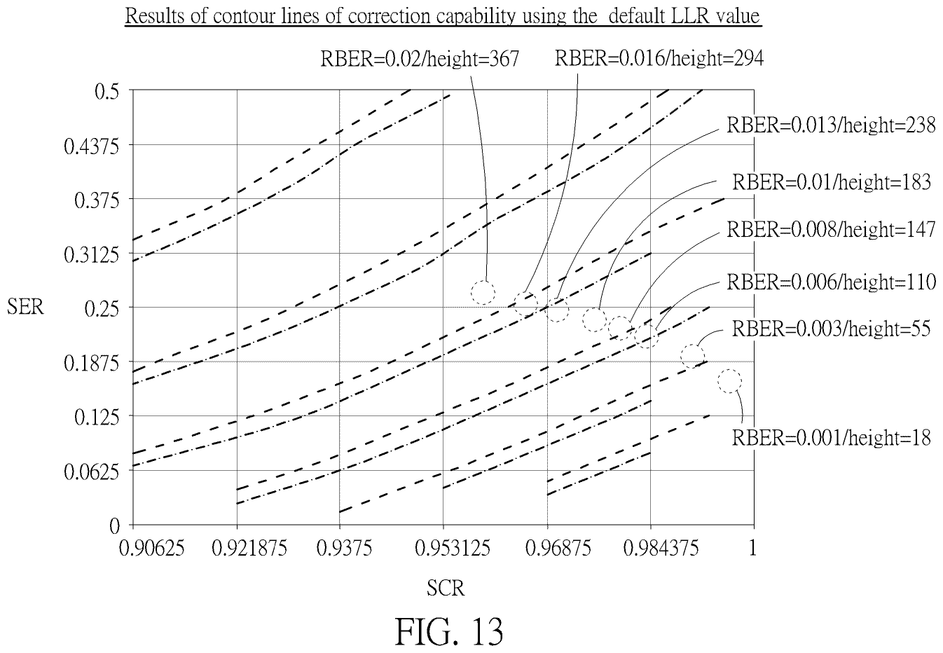

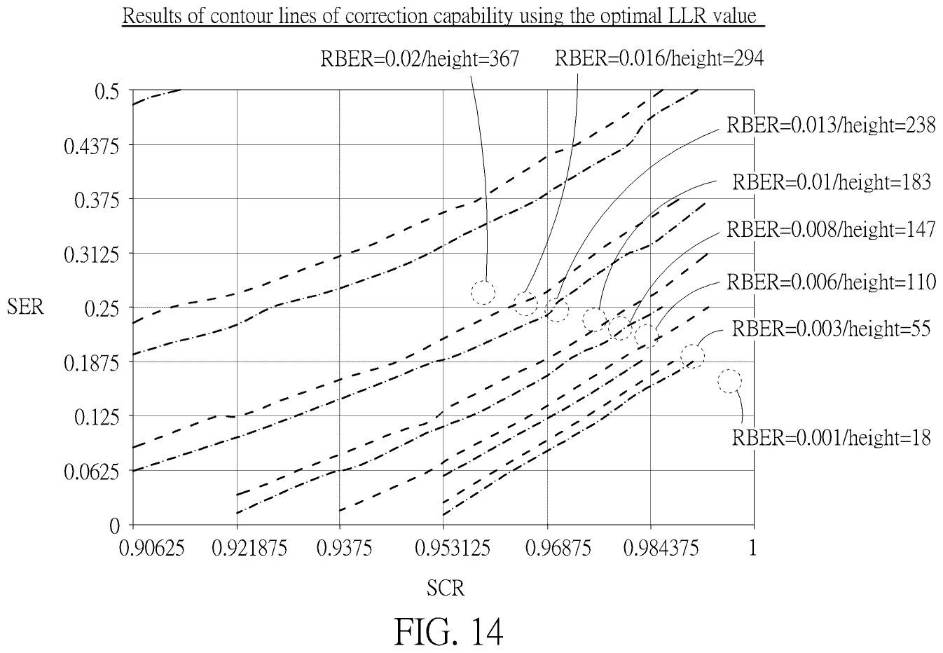

In the following, the performance comparison of different examples using the default/preset LLR value and the optimal LLR value is provided, so that readers can clearly understand the difference in decoding capabilities between the two examples. FIG. 13 is a diagram of the results of the contour lines of correction capability using the preset LLR value. FIG. 14 is a schematic diagram of the results of the contour lines of correction capability using the optimal LLR value. In comparison, as shown in FIG. 14, when the optimal LLR value is used, the lines of the contour lines of correction capability move to the upper left corner, and this means that the error correction capability of the decoder 110DE has been improved. For example, when the SCR is 0.96875, the SER is 0.0625, and the error rate is 1e−8, the correction capability using the preset LLR value is between 350 and 400 bits. However, if the optimal LLR value is used, the error correction capability can be improved up to a range greater than 400 bits.

In addition, as mentioned in the previous paragraphs, in the ideal AWGN model, the distance between NS point and PS point is a half of the standard deviation. When the standard deviation becomes larger, the distance between NS point and PS point will increase accordingly. This distance is called as soft sensing step size indicated by Δ value. A different Δ value may change the ratio between strong bits and weak bits, to further change the values of strong correct rate SCR and strong error rate SER. In one embodiment, in addition to changing and optimizing the LLR value by the decoder 110DE, the host device 101 (or the flash memory controller 100) may also change the setting of Δ value at the side of the NAND-type flash memory to further improve the decoder's error correction capability.

In the actual application scenario of an NAND-type flash memory, it is usually difficult to know the actual standard deviation of the potential distribution. Therefore, a conventional method is often to configure the setting of Δ value based on past operating experiences. By using the operations of the present invention, the host device 101 (or the flash memory controller 100) can optimally configure the setting of Δ value. In the following the ideal AWGN model is provided as an example to describe the setting operation for optimizing the Δ value by a flash memory controller according to an embodiment of the present invention.

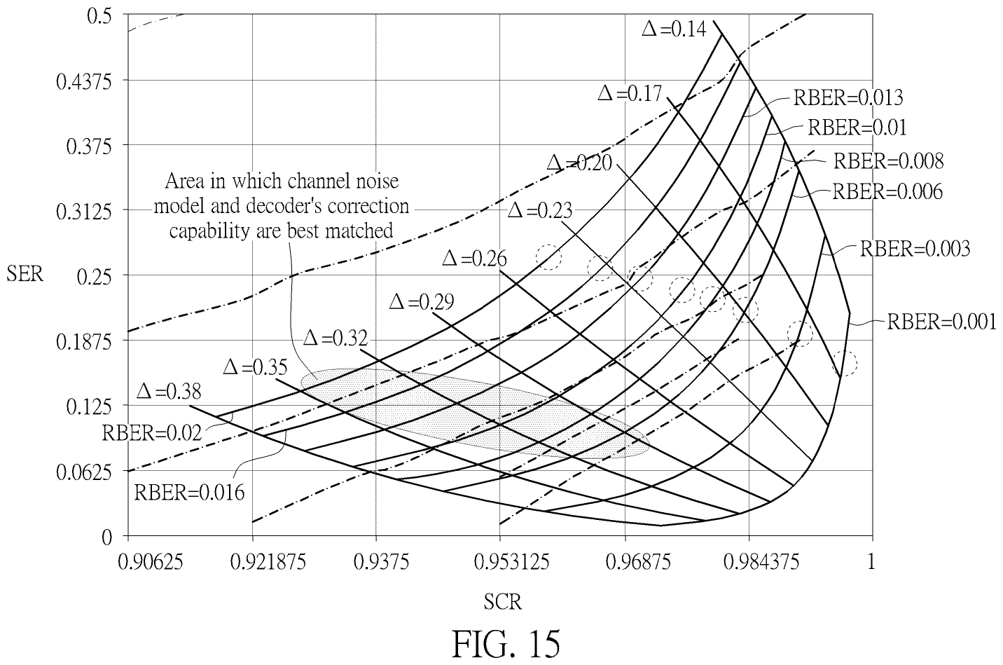

Please refer to FIG. 15. FIG. 15 is a schematic diagram of the mesh structure of the SCR/SER combinations under different Δ values under the ideal AWGN model according to an embodiment of the present invention. As shown in FIG. 15, for example, it shows the SCR/SER combinations at different Δ values under the ideal AWGN model. For example, in the mesh structure, the Δ values range from 0.14, 0.17, 0.2, 0.23, 0.26, 0.29, 0.32, 0.35 and 0.38, and the multiple curved lines (from upper left to lower right) are formed by the different combinations of the SCR/SER coordinate points at the different Δ values. The Δ value is between 0 and 1, and it represents one unit distance between two potentials; however, this is not intended to be a limitation of the present invention. In addition, in the mesh structure, multiple curve lines having directions from the upper right to the lower left respectively represent different height values at the Z-axis in the three-dimensional space mentioned above corresponding to the different raw bit error rate (RBER) values (or which may be converted into the average numbers of error bits). The curve lines form the mesh structure which presents the Gaussian model, and have a shape which is like to a catcher's mitt/glove.

The host device 101 (or the flash memory controller 100) of the present invention can statistically analyze and obtain a region in which the AWGN model and the decoding correction capability are best matched, by comparing the lines of the mesh structure with the contour lines (dashed-dotted lines) of the decoding correction capability of the LDPC decoder 110DE. The best matched region/area is a region/area in which the lines of AWGN noise mode and the lines of the decoding correction capability are almost parallel to each other. That is, such region/area is a region/area in which a smallest angle is formed and intersected by line(s) of the mesh structure of Gaussian model and line(s) of the decoding correction capability, e.g. a match area indicated by an oval-shaped object as shown in FIG. 15. Therefore, in an embodiment of the present invention, under a condition that given the raw bit error rate RBER, the host device 101 (or the flash memory controller 100) can adjust the different Δ values so as to make the adjusted Δ value fall within the match area marked in FIG. 15, and controls the LDPC decoder 110DE to adopt an optimal LLR value corresponding to a relative coordinate point, so as to make the decoder 110De achieve the optimal decoding correction capability. For example (but not limited to), when the raw bit error rate RBER is equal to 0.02 and the Δ value is equal to 0.17, the maximum correction capability may be approximately equal to 200 bits. Under the same condition, by modifying the Δ value as 0.35 and selecting the LLR1 value as 4 and the LLR2 value as 13, this can increase the error correction capability to nearly 250 bits. These examples are not limitations of the present invention.

In practice, even if the noise model is not yet the AWGN model, the embodiments of the present invention can use a pre-mass-production testing for each batch of real NAND-type flash memories during mass production to perform the statistical analysis operation to draw a mesh structure (but not limited to) as shown in FIG. 15 to determine the setting value of the Δ value. In addition, in another embodiment, during the use of NAND-type flash memory products, the embodiment of the present invention can also select one from different Δ values corresponding to a plurality of preset scenarios and different scenarios, to try to find out the setting value of Δ value which is best matched to the decoder.

To sum up, the method of improving the decoder's capability of the embodiment of the present invention is to construct a three-dimensional space of N4 noise model. The decoding method is performed based on the minimum amount of soft message passing for non-Gaussian noise to effectively find out the optimal LLR value and the optimal Δ value under a condition of complex operating environment, to enhance the decoder's decoding capability up to its maximum potential.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A decoding method used in a decoder of a flash memory controller, comprising:
after decoding a codeword stored in a flash memory, comparing a decoded result of the codeword with a pre-decoded data of the codeword to obtain at least one statistical description parameter for describing the codeword in a three-dimensional space;
determining whether a soft sensing step size, which is currently used, matches a log likelihood ratio of the decoder;
when the soft sensing step size, which is currently used, does not match the log likelihood ratio of the decoder, changing and adjusting the soft sensing step size, and calculating a change of the soft sensing step size, which has been adjusted, for a change information caused by the at least one statistical description parameter to predict a match combination of a corresponding soft sensing step size and a corresponding log likelihood ratio; and
using the match combination of the predicted corresponding soft sensing step size and the predicted corresponding log likelihood ratio to read a next codeword stored in the flash memory.

2. The decoding method of claim 1, wherein the at least one statistical description parameter comprises a strong correct rate, a strong error rate, and a number of error bits.

3. The decoding method of claim 2, further comprising:
using a parameter combination of the strong correct rate, the strong error rate, and the number of error bits to depict a coordinate point of the codeword in the three-dimensional space in a specific noise model.

4. The decoding method of claim 1, further comprising:
calculating the change information, which is caused by the change of the adjusted soft sensing step size, of the at least one statistical description parameter to obtain at least one parameter combination corresponding to the match combination of the predicted corresponding soft sensing step size and the predicted corresponding log likelihood ratio, to make a coordinate point of the at least one parameter combination in the three-dimensional space fall within a specific match area; and, the specific match area is an area in which a smallest angle is formed by a line of a mesh structure of a specific noise model and a line of a decoding correction capability corresponding to the corresponding log-likelihood ratio.

5. The decoding method of claim 1, further comprising:
storing the match combination of the predicted soft sensing step size and the corresponding log-likelihood ratio in a storage circuit or a firmware unit within the flash memory controller.

6. A flash memory testing method, comprising:
before a mass production of a batch of flash memories, performing a pre-burn-in test upon the batch of flash memories;
performing a read and write test upon the batch of flash memories under multiple different usage conditions to statistically obtain multiple different combinations of at least one statistical description parameter;
using multiple different soft sensing step sizes to perform a read test upon the batch of flash memories under the multiple different usage conditions, to statistically obtain multiple variation combinations of the at least one statistical description parameter respectively corresponding to the multiple different soft sensing step sizes;
statistically obtaining multiple parameter combinations of the at least one statistical description parameter respectively corresponding to the multiple different soft sensing step sizes used under the multiple different usage conditions according to the multiple variation combinations of the at least one statistical description parameter;
depicting a graph of multiple different parameter combinations of the at least one statistical description parameter respectively corresponding to the multiple different soft sensing step sizes of the batch of flash memories to project the graph into a specific noise model to form a mesh structure; and
comparing and matching the mesh structure in the specific noise model with at least one contour line of an error bit correction capability of a decoder in a flash memory controller to obtain multiple corresponding optimal match combination information under the multiple different usage conditions to write and store a setting of the multiple corresponding optimal match combination information in a storage circuit or a firmware unit in the flash memory controller.

7. The decoding method of claim 6, wherein the at least one statistical description parameter comprises a strong correct rate, a strong error rate, and an error bit number.

8. The decoding method of claim 6, wherein the batch of flash memories are multiple flash memories with parameters of the same process type.

9. The decoding method of claim 6, wherein the multiple corresponding optimal match combination information indicates multiple optimal log likelihood ratios and multiple optimal soft sensing step sizes under the multiple different usage conditions.

10. The decoding method of claim 6, wherein the multiple different usage conditions comprise multiple different wear and tear conditions, multiple different writing times, or multiple different read and write temperature conditions.

11. A flash memory controller, to be coupled between a host device and a flash memory, comprising:
an encoder, for performing an encoding operation upon a write data which is to be written into the flash memory by the host device;
a decoder, for performing a decoding operation upon a data stored by the flash memory; and
a control unit, coupled to the encoder and the decoder, for control the encoding operation and the decoding operation;
wherein after the decoder decodes a codeword stored in the flash memory, the control unit is used for:
comparing a decoded result of the codeword with a pre-decoded data of the codeword to obtain at least one statistical description parameter for describing the codeword in a three-dimensional space;
determining whether a soft sensing step size, which is currently used, matches a log likelihood ratio of the decoder;
when the soft sensing step size, which is currently used, does not match the log likelihood ratio of the decoder, changing and adjusting the soft sensing step size, and calculating a change of the soft sensing step size, which has been adjusted, for a change information caused by the at least one statistical description parameter to predict a match combination of a corresponding soft sensing step size and a corresponding log likelihood ratio; and
using the match combination of the predicted corresponding soft sensing step size and the predicted corresponding log likelihood ratio to read and decode a next codeword stored in the flash memory.

12. The decoder of claim 11, wherein the at least one statistical description parameter comprises a strong correct rate, a strong error rate, and a number of error bits.

13. The decoder of claim 12, wherein the control unit is used for using a parameter combination of the strong correct rate, the strong error rate, and the number of error bits to depict a coordinate point of the codeword in the three-dimensional space in a specific noise model.

14. The decoder of claim 11, wherein the control unit is used for:
calculating the change information, which is caused by the change of the adjusted soft sensing step size, of the at least one statistical description parameter to obtain at least one parameter combination corresponding to the match combination of the predicted corresponding soft sensing step size and the predicted corresponding log likelihood ratio, to make a coordinate point of the at least one parameter combination in the three-dimensional space fall within a specific match area; and, the specific match area is an area in which a smallest angle is formed by a line of a mesh structure of a specific noise model and a line of a decoding correction capability corresponding to the corresponding log-likelihood ratio.

15. The decoder of claim 11, wherein the control unit is used for storing the match combination of the predicted soft sensing step size and the corresponding log-likelihood ratio in a storage circuit or a firmware unit within the flash memory controller.

16. A host device used for testing a flash memory, comprising:
a storage circuit; and
a processor circuit, coupled to the storage circuit, being used for:
before a mass production of a batch of flash memories, performing a pre-burn-in test upon the batch of flash memories;
performing a read and write test upon the batch of flash memories under multiple different usage conditions to statistically obtain multiple different combinations of at least one statistical description parameter;
using multiple different soft sensing step sizes to perform a read test upon the batch of flash memories under the multiple different usage conditions, to statistically obtain multiple variation combinations of the at least one statistical description parameter respectively corresponding to the multiple different soft sensing step sizes;
statistically obtaining multiple parameter combinations of the at least one statistical description parameter respectively corresponding to the multiple different soft sensing step sizes used under the multiple different usage conditions according to the multiple variation combinations of the at least one statistical description parameter;
depicting a graph of multiple different parameter combinations of the at least one statistical description parameter respectively corresponding to the multiple different soft sensing step sizes of the batch of flash memories to project the graph into a specific noise model to form a mesh structure; and
comparing and matching the mesh structure in the specific noise model with at least one contour line of an error bit correction capability of a decoder in a flash memory controller to obtain multiple corresponding optimal match combination information under the multiple different usage conditions to write and store a setting of the multiple corresponding optimal match combination information in a storage circuit or a firmware unit in the flash memory controller.

17. The host device of claim 16, wherein the at least one statistical description parameter comprises a strong correct rate, a strong error rate, and an error bit number.

18. The host device of claim 16, wherein the batch of flash memories are multiple flash memories with parameters of the same process type.

19. The host device of claim 16, wherein the multiple corresponding optimal match combination information indicates multiple optimal log likelihood ratios and multiple optimal soft sensing step sizes under the multiple different usage conditions.

20. The host device of claim 16, wherein the multiple different usage conditions comprise multiple different wear and tear conditions, multiple different writing times, or multiple different read and write temperature conditions.
